(19) United States
(12) Patent Application Publication
(10) Pub. No.: US 2026/0085446 A1
(43) Pub. Date: Mar. 26, 2026

(54) SILICON CARBIDE SEMICONDUCTOR DEVICE INCLUDING A BUFFER LAYER AND MANUFACTURING METHOD

(71) Applicant: Infineon Technologies AG, Neubiberg (DE)

(72) Inventors: Christian Zmölnig, Lurnfeld (AT); Thomas Söllradl, Arnoldstein (AT); Christoffer Erbert, St. Magdalen (AT)

(21) Appl. No.: 19/317,296

(22) Filed: Sep. 3, 2025

(30) Foreign Application Priority Data
Sep. 23, 2024 (DE) 102024209087.5

(51) Int. Cl. C30B 25/18; C30B 25/20; C30B 29/36; H01L 21/02; H10D 62/60; H10D 62/832

(52) U.S. Cl. CPC C30B 25/183; C30B 25/20; C30B 29/36; H10D 62/60; H10D 62/8325; H10P 14/20; H10P 14/2904; H10P 14/3208; H10P 14/3408

(57) ABSTRACT

A silicon carbide (SiC) semiconductor device is proposed. The SiC semiconductor device includes a buffer layer of a first conductivity type and a drift layer of the first conductivity type arranged, along a vertical direction, on the buffer layer. A vertical profile of a doping concentration of the buffer layer includes at least a first valley portion, a first plateau portion and a first transition portion extending from the first valley portion to the first plateau portion. The doping concentration of each of the first valley portion or the first plateau portion varies by less than 20 %. A vertical extent of the first transition portion ranges from 1 % to 30 % of a vertical extent of the first valley portion.

### TECHNICAL FIELD

The present disclosure relates to a silicon carbide (SiC) semiconductor device, in particular to a SiC semiconductor device including a buffer layer.

### BACKGROUND

Technology development of new generations of SiC semiconductor devices, e.g. insulated gate field effect transistors (IGFETs) such as metal oxide semiconductor field effect transistors (MOSFETs) or insulated gate bipolar transistors (IGBTs), aims at improving electrical device characteristics and reducing costs by shrinking device geometries. Although costs may be reduced by shrinking device geometries, a variety of tradeoffs and challenges have to be met when increasing device functionalities per unit area. For example, increasing the voltage blocking capability, e.g. drain-to-source breakdown voltage or collector-to-emitter breakdown voltage, may be challenging in view of reliability constraints caused by, for example, process-related incorporation of stress in deposited layers that may depend on, for example, doping level and/or thickness of deposited layers.

There is a need for improving the tradeoff between voltage blocking capability and reliability of SiC semiconductor devices.

### SUMMARY

An example of the present disclosure relates to a semiconductor device including a SiC semiconductor body. The SiC semiconductor device includes a buffer layer of a first conductivity type. The SiC semiconductor device further includes a drift layer of the first conductivity type arranged, along a vertical direction, on the buffer layer. A vertical profile of a doping concentration of the buffer layer includes at least a first valley portion, a first plateau portion, and a first transition portion extending from the first valley portion to the first plateau portion. The doping concentration of each of the first valley portion, or the first plateau portion varies by less than 20 %. A vertical extent of the first transition portion ranges from 1 % to 30 % of a vertical extent of the first valley portion.

Another example of the present disclosure relates to a method of manufacturing a SiC semiconductor device. The method includes forming a buffer layer of a first conductivity type. The method further includes forming a drift layer of the first conductivity type arranged, along a vertical direction, on the buffer layer. A vertical profile of a doping concentration of the buffer layer includes at least a first valley portion, a first plateau portion, and a first transition portion from the first valley portion to the first plateau portion. The doping concentration of each of the first valley portion, or the first plateau portion varies by less than 20 %. A vertical extent of the first transition portion ranges from 1 % to 30 % of a vertical extent of the first valley portion.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1A schematically and exemplarily illustrates a cross-sectional view of a SiC semiconductor device including a drift layer on a buffer layer.

FIG. 1B is a graph for schematically and exemplarily illustrating a profile of doping concentration along a vertical direction of a portion of the buffer layer of FIG. 1A.

FIGS. 2 and 3 are graphs for illustrating further exemplary profiles of doping concentration along the vertical direction of a portion of the buffer layer of FIG. 1A.

FIG. 4 is a schematic cross-sectional view for illustrating a configuration example of a SiC semiconductor device including a drift layer on a buffer layer.

FIG. 5 is an exemplary process illustration of manufacturing a SiC semiconductor device.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on”said substrate).

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A configuration example of a silicon carbide, SiC, semiconductor device includes a buffer layer of a first conductivity type.

The SiC semiconductor device further includes a drift layer of the first conductivity type arranged, along a vertical direction, on the buffer layer.

A vertical profile of a doping concentration of the buffer layer may include at least a first valley portion, a first plateau portion, and a first transition portion extending from the first valley portion to the first plateau portion. The doping concentration of each of the first valley portion, or the first plateau portion may vary by less than 20 %, or by less than 10 %. A vertical extent of the first transition portion may range from 1 % to 30 %, or from 1 % to 20 %, or from 1 % to 10 % of a vertical extent of the first valley portion.

For example, p-type dopants in SiC may include Al, B, Be, Ga, or any combination thereof. For example, n-type dopants in SiC may include N, P, or any combination thereof. The first conductivity type may be an n-type and the second conductivity type may be a p-type, or, alternatively, the first conductivity type may be a p-type and the second conductivity type may be an n-type.

The SiC semiconductor device may be part of an integrated circuit or may be a discrete semiconductor device or a semiconductor module, for example. The SiC semiconductor device may be or may include an insulated gate field effect transistor (IGFET) such as a metal oxide semiconductor field effect transistor (MOSFET) or an insulated gate bipolar transistor (IGBT), for example. The SiC semiconductor device may be a vertical semiconductor device having a load current flow between the first surface and a second surface opposite to the first surface along a vertical direction. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter of an IGBT, or between drain and source of a MOSFET, in the range of several hundreds of up to several thousands of volts, e.g. 1.7 kV, 3.3 kV, 4.5 kV, 5.5 kV, 6 kV, 6.5 kV, 10 kV, 12 kV. The blocking voltage may correspond to a voltage class specified in a datasheet of the power semiconductor device, for example. The SiC semiconductor device may be used in applications related to power transmission and distribution, automotive and transport, renewable energy, consumer electronics, and other industrial applications, for example.

The SiC semiconductor device may be based on a SiC semiconductor body from a crystalline SiC material. The crystalline SiC material may have a hexagonal crystal lattice, by way of example. For example, the semiconductor material may be 2H-SiC (SiC of the 2H polytype), 6H-SiC or 15R-SiC. According to an example, the semiconductor material is silicon carbide of the 4H polytype (4H-SiC). The SiC semiconductor body may include or consist of a semiconductor substrate having one or more than one semiconductor layers, e.g. epitaxially grown layers, thereon.

The drift layer may be arranged, along the vertical direction, between the buffer layer and a first surface of the SiC semiconductor body. The first surface may define a front surface or a top surface of the SiC semiconductor body. The buffer layer may be arranged, along the vertical direction, between the drift layer and a second surface of the SiC semiconductor body. The second surface may define a back surface or a rear surface of the SiC semiconductor body, for example. The SiC semiconductor body may be attached to a lead frame via the second surface, for example. Over the first surface of the SiC semiconductor body, bond pads may be arranged and bond wires may be bonded on the bond pads, for example.

For realizing a desired current carrying capacity, the SiC semiconductor device may be designed by a plurality of parallel-connected SiC semiconductor device cells. The parallel-connected SiC semiconductor device cells may, for example, be SiC semiconductor device cells formed in the shape of a strip or a strip segment. Of course, the SiC semiconductor device cells can also have any other shape, e.g. circular, elliptical, polygonal such as hexagonal or octahedral. The semiconductor device cells may be arranged in a transistor cell area of the SiC semiconductor body. The transistor cell area may be an area where an emitter region of an IGBT (or a source region of a MOSFET) and a collector region of an IGBT (or a drain region of a MOSFET) are arranged opposite to one another along a vertical direction. In the transistor cell area, a load current may enter or exit the SiC semiconductor body of the semiconductor device, e.g. via contact plugs or contact lines on the top surface of the mesa. The semiconductor device may further include an edge termination area that may include a termination structure. In a blocking mode or in a reverse biased mode of the SiC semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

Other than doping concentration profiles formed by a plurality of overlapping ion implantation peak profiles, the profiles of doping concentration described herein may be approximated by a rectangular or square-wave shape. The vertical extents of the transition region between the valley and plateau portions may be smaller than vertical extents of the related valley and plateau portions.

The buffer layer described in the examples herein includes areas of tensile and compressive stress that result in an intrinsic stress reduction due to the counteraction of different stress directions. This may counteract gliding of crystal defects and improving the trade-off between voltage blocking capability and reliability of SiC semiconductor devices.

For example, the vertical extent of the first transition portion may range from 1 % to 30 %, or from 1% to 20 %, or from 1% to 10 %, of a vertical extent of the first plateau portion.

For example, the doping concentration of the first plateau portion may range from 1×10¹⁷ cm⁻³ to 1×10¹⁹ cm⁻³, or from 1×10¹⁸ cm⁻³ to 1×10¹⁹ cm⁻³.

For example, a doping concentration of the first valley portion may range from 1×10¹⁶ cm⁻³ to 1×10¹⁸ cm⁻³, or from 1×10¹⁷ cm⁻³ to 1×10¹⁸ cm⁻³.

For example, the vertical extent of the first plateau portion and the vertical extent of the first valley portion may be equal or may differ by less than 20 %.

For example, the vertical extent of the first valley portion may range from 100 nm to 2 μm, or from 200 nm to 1.5 μm.

For example, the buffer layer may further include an end portion adjoining the drift layer. A profile of a doping concentration of the end portion may continuously decrease toward the drift layer. In the drift layer, the doping concentration may be constant along the vertical direction or may be constant in vertical segments thereof.

For example, the buffer layer may further include a second plateau portion and a second transition portion extending from the second plateau portion to the first valley portion. In some examples, further plateau and/or valley portions may be present or included in the buffer layer. For example, a vertical extent of the second plateau portion and a vertical extent of the first plateau may be equal or may differ by less than 20 %.

For example, the doping concentration of the second plateau portion may vary by less than 20 %. A vertical extent of the second transition portion may range from 1 % to 30 %, or from 1% to 20 %, or from 1% to 10 % of the vertical extent of the first valley portion.

For example, an average doping concentration of the second plateau portion and an average doping concentration of the first plateau portion may be equal or may differ by less than 20 %, or by less than 10 %.

For example, an average doping concentration of the second plateau portion may be a factor of 1.5 to 30 larger than an average doping concentration of the first plateau portion.

For example, a vertical extent of the second plateau portion and a vertical extent of the first valley portion may be equal or may differ by less than 20 %, or by less than 10 %.

For example, the buffer layer may further include a second valley portion and a third transition portion extending from the first plateau portion to the second valley portion. A doping concentration of the second valley portion may vary by less than 20 %, or by less than 10 %. A vertical extent of the third transition portion may range from 1 % to 30 %, or from 1% to 20 %, or from 1% to 10 % of a vertical extent of the second valley portion.

For example, an average doping concentration of the second valley portion and an average doping concentration of the first valley portion may differ by less than 20 %, or by less than 10 %.

For example, an average doping concentration of the first valley portion may be by a factor of 1.5 to 30 larger than an average doping concentration of the second valley portion.

For example, the vertical profile of a doping concentration of the first valley portion, the first plateau portion, and the first transition portion may be an in-situ doping concentration profile. An in-situ doping concentration profile may allow for increasing vertical extents of the valley and/or plateau portion compared to doping concentration profiles formed by one or more ion implantations of dopants. Likewise, an in-situ doping concentration profile may allow for decreasing vertical extents of the transition portion compared to doping concentration profiles formed by one or more ion implantations of dopants. Since broadening of dopant concentration profiles by diffusion in view of the thermal budget during formation of the device is small in SiC compared to silicon, the above characteristics are even more pronounced and SiC regions defined by in-situ doping concentration profiles and SiC regions defined by ion implantation profiles are substantially different in structure in view of the profile of incorporated dopants.

The above exemplary profile characteristics or combinations thereof may be combined for reducing intrinsic stress in the buffer layer due to the counteraction of different stress directions, thereby also counteracting gliding of crystal defects and improving the trade-off between voltage blocking capability and reliability of SiC semiconductor devices.

Details with respect to structure, or function, or technical benefit of features described above with respect to a semiconductor device such as a FET, or IGBT likewise apply to the exemplary methods described further below. Processing the SiC semiconductor body may comprise one or more optional additional features corresponding to one or more aspects mentioned in connection with the proposed concept or one or more examples described above or below.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, processes, -operations or -steps, respectively. Such sub acts may be included and part of the disclosure of this single act unless explicitly excluded.

An example of a method of manufacturing a silicon carbide, SiC, semiconductor device includes forming a buffer layer of a first conductivity type. The method further includes forming a drift layer of the first conductivity type arranged, along a vertical direction, on the buffer layer. A vertical profile of a doping concentration of the buffer layer may include at least a first valley portion, a first plateau portion, and a first transition portion from the first valley portion to the first plateau portion. The doping concentration of each of the first valley portion, or the first plateau portion may vary by less than 20 %, or by less than 10 %. A vertical extent of the first transition portion may range from 1 % to 30 %, or from 1 % to 20 %, or from 1 % to 10 % of a vertical extent of the first valley portion.

For example, the vertical profile of a doping concentration of the first valley portion, the first plateau portion, and the first transition portion may be formed by in-situ doping. In-situ doping may allow for forming rectangular or square-wave shape doping concentration profiles by controlling the supply of dopant gases to the reactant gases with respect to amount and temporal change, for example.

For example, the buffer layer may be formed on a SiC substrate by an epitaxial layer deposition process. The drift layer may be formed on the buffer layer by an epitaxial layer deposition process. The profile of a doping concentration of the buffer layer including at least the first valley portion, the first plateau portion, and the first transition portion may be adjusted or formed before forming the drift layer on the buffer layer, for example. The buffer layer and the drift layer on the buffer layer may be formed without interruption of the epitaxial layer deposition process, i.e. after formation of the buffer layer and before formation of the drift layer, by ion implantation processes into the buffer layer, for example.

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

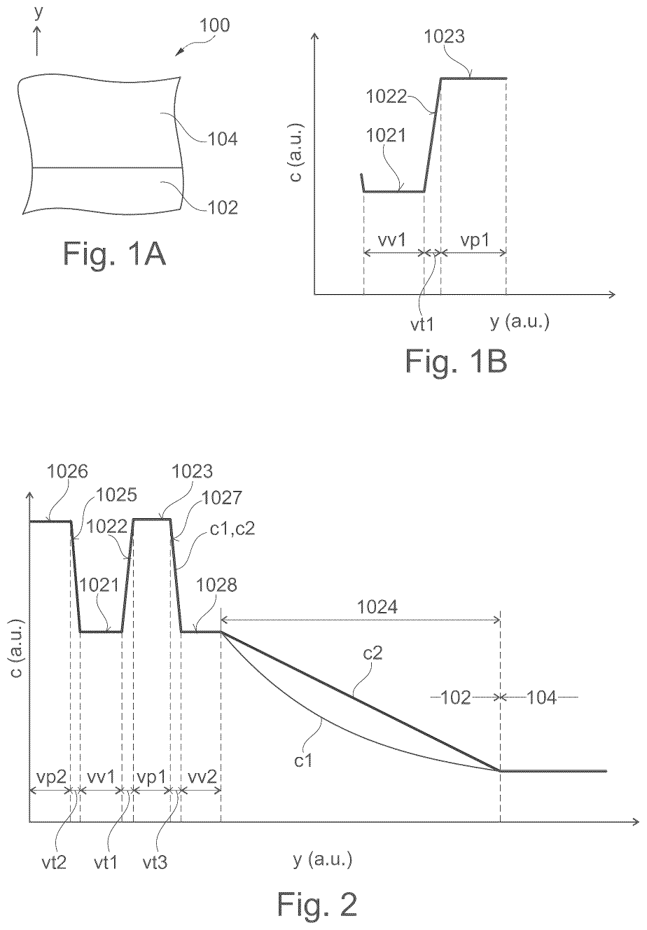

A configuration example of a SiC semiconductor device 100 is illustrated in the schematic cross-sectional view of FIG. 1A. In the graph of FIG. 1B, an example of a profile of doping concentration c along a vertical direction of the SiC semiconductor device 100 of FIG. 1A is illustrated.

Referring to FIG. 1A, the SiC semiconductor device includes a buffer layer 102 of a first conductivity type. Along a vertical direction y, a drift layer 104 of the first conductivity type is formed on the buffer layer 102. The buffer layer 102 may be formed on a SiC base substrate, which, for example, may be thinned or even removed during manufacturing of the SiC semiconductor device 100.

Referring to FIG. 1B, a vertical profile of a doping concentration c of the buffer layer 102 includes a first valley portion 1021. The profile further includes a first plateau portion 1023. The profile further includes a first transition portion 1022 that extends from the first valley portion 1021 to the first plateau portion 1023. The profile may be an in-situ doping concentration profile. The doping concentration c of the first valley portion 1021 varies by less than 20 %. Likewise, the doping concentration c of the first plateau portion 1023 varies by less than 20 %. A vertical extent vt1 of the first transition portion 1022 ranges from 1 % to 30 % of a vertical extent vv1 of the first valley portion 1021, or ranges from 1 % to 30 % of a vertical extent vp1 of the first plateau portion 1023.

Further examples of doping concentration along a vertical direction of the SiC semiconductor device 100 are illustrated in the graph of FIG. 2.

The buffer layer 102 associated with each of the profiles c1, c2 further includes an end portion 1024 adjoining the drift layer 104. While both profiles c1, c2 continuously decrease toward the drift layer 104, a gradient of the profile c1 also decreases toward the drift layer 104. The drift layer 104 is exemplified by a constant doping concentration.

The buffer layer 102 associated with each of the profiles c1, c2 further includes a second plateau portion 1026 and a second transition portion 1025 extending from the second plateau portion 1026 to the first valley portion 1021. The doping concentration of the second plateau portion 1026 varies by less than 20 %. A vertical extent vt2 of the second transition portion 1025 ranges from 1 % to 30 % of the vertical extent vv1 of the first valley portion 1021. An average doping concentration of the second plateau portion 1026 differs by less than 20 %. Likewise, an average doping concentration of the first plateau portion 1023 differs by less than 20 %.

In the buffer layer 102 associated with each of the profiles c1, c2, a vertical extent vp2 of the second plateau portion 1026 and a vertical extent vv1 of the first valley portion 1021 differ by less than 20 %.

The buffer layer 102 further includes a second valley portion 1028 and a third transition portion 1027. The third transition portion 1027 extends from the first plateau portion 1023 to the second valley portion 1028. A doping concentration of the second valley portion 1028 varies by less than 20 %. A vertical extent vt3 of the third transition portion 1027 ranges from 1 % to 30 % of a vertical extent vv2 of the second valley portion 1028.

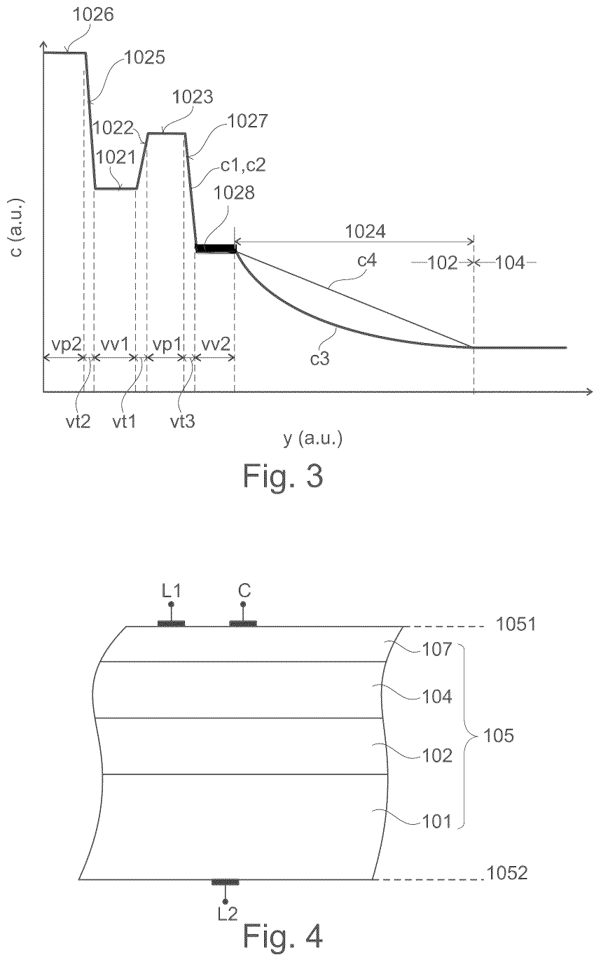

Further examples of doping concentration along a vertical direction of the SiC semiconductor device 100 are illustrated in the graph of FIG. 3.

In the end portion 1024 adjoining the drift layer 104, the doping concentration profiles c3, c4 are similar to the doping concentration profiles c1, c2 of FIG. 2, respectively. Other than the exemplary doping profiles c1, c2 illustrated in FIG. 2, an average doping concentration of the second plateau portion 1026 is a factor of 1.5 to 30 larger than an average doping concentration of the first plateau portion 1023. Likewise, an average doping concentration of the first valley portion 1021 is a factor of 1.5 to 30 larger than an average doping concentration of the second valley portion 1028.

The buffer layer 102 may be part of a SiC semiconductor device 100 as illustrated in the schematic cross-sectional view of FIG. 4, for example.

The SiC semiconductor device 100 includes the buffer layer 102 as described in the examples herein. The buffer layer 102 is formed on a SiC semiconductor base substrate 101. In some examples, the semiconductor base substrate 101 may be partly or completely removed. Over the drift layer 104, an active device layer 107 is formed. The active device layer 107 includes one or more doped regions for realizing a desired device functionality, e.g. transistor cell functionality. The semiconductor base substrate 101, the buffer layer 102, the drift layer 104 and the active device layer 107 are parts of a SiC semiconductor body 105 having a first surface 1051 and a second surface 1052.

A first load electrode L1 is arranged on the first surface of the SiC semiconductor body 105 and is electrically coupled to the active device layer, e.g. to a source region of a MOSFET or to an emitter region of an IGBT. The first load electrode L1 is part of a wiring area over the first surface 1051 of the SiC semiconductor body 105. A control electrode C is arranged on and/or below the first surface 1051 of the SiC semiconductor body. The control electrode C may be a gate electrode of a planar gate or a trench gate transistor, for example. A second load electrode L2 is arranged on the second surface 1052 of the SiC semiconductor body 105 and is electrically coupled to the drift layer 104.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, processes, -operations or -steps, respectively. Such sub acts may be included and part of the disclosure of this single act unless explicitly excluded.

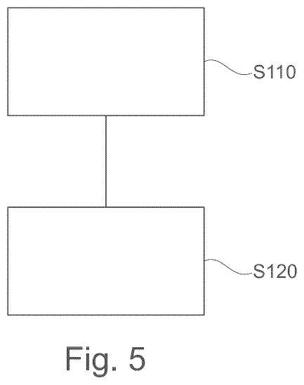

An example of a method of manufacturing a semiconductor device is illustrated by referring to the flowchart of FIG. 5.

Process feature S110 includes forming a buffer layer of a first conductivity type.

Process feature S120 forming a drift layer of the first conductivity type arranged, along a vertical direction, on the buffer layer, wherein a vertical profile of a doping concentration of the buffer layer includes at least a first valley portion, a first plateau portion, and a first transition portion from the first valley portion to the first plateau portion, wherein the doping concentration of each of the first valley portion, or the first plateau portion varies by less than 20 %, and a vertical extent of the first transition portion ranges from 1 % to 30 % of a vertical extent of the first valley portion.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A silicon carbide (SiC) semiconductor device, comprising:
a buffer layer of a first conductivity type;
a drift layer of the first conductivity type arranged, along a vertical direction, on the buffer layer,
wherein a vertical profile of a doping concentration of the buffer layer includes at least a first valley portion, a first plateau portion and a first transition portion extending from the first valley portion to the first plateau portion,
wherein a doping concentration of each of the first valley portion or the first plateau portion varies by less than 20 %, and
wherein a vertical extent of the first transition portion ranges from 1 % to 30 % of a vertical extent of the first valley portion.

2. The SiC semiconductor device of claim 1, wherein the vertical extent of the first transition portion ranges from 1 % to 30 % of a vertical extent of the first plateau portion.

3. The SiC semiconductor device of claim 1, wherein the doping concentration of the first plateau portion ranges from 1×10¹⁷ cm⁻³ to 1×10¹⁹ cm⁻³.

4. The SiC semiconductor device of claim 1, wherein a doping concentration of the first valley portion ranges from 1×10¹⁶ cm⁻³ to 1×10¹⁸ cm⁻³.

5. The SiC semiconductor device of claim 1, wherein a vertical extent of the first plateau portion and the vertical extent of the first valley portion differ by less than 20 %.

6. The SiC semiconductor device of claim 1, wherein the vertical extent of the first valley portion ranges from 100 nm to 2 μm.

7. The SiC semiconductor device of claim 1, wherein the buffer layer further includes an end portion adjoining the drift layer, and wherein a profile of a doping concentration of the end portion continuously decreases toward the drift layer.

8. The SiC semiconductor device of claim 1, wherein the buffer layer further includes a second plateau portion and a second transition portion extending from the second plateau portion to the first valley portion.

9. The SiC semiconductor device of claim 8, wherein a doping concentration of the second plateau portion varies by less than 20 %, and wherein a vertical extent of the second transition portion ranges from 1 % to 30 % of the vertical extent of the first valley portion.

10. The SiC semiconductor device of claim 8, wherein an average doping concentration of the second plateau portion and an average doping concentration of the first plateau portion differ by less than 20 %.

11. The SiC semiconductor device of claim 8, wherein an average doping concentration of the second plateau portion is a factor of 1.5 to 30 larger than an average doping concentration of the first plateau portion.

12. The SiC semiconductor device of claim 8, wherein a vertical extent of the second plateau portion and the vertical extent of the first valley portion differ by less than 20 %.

13. The SiC semiconductor device of claim 1, wherein the buffer layer further includes a second valley portion and an additional transition portion extending from the first plateau portion to the second valley portion, wherein a doping concentration of the second valley portion varies by less than 20 %, and wherein a vertical extent of the additional transition portion ranges from 1 % to 30 % of a vertical extent of the second valley portion.

14. The SiC semiconductor device of claim 13, wherein an average doping concentration of the second valley portion and an average doping concentration of the first valley portion differ by less than 20 %.

15. The SiC semiconductor device of claim 13, wherein an average doping concentration of the first valley portion is a factor of 1.5 to 30 larger than an average doping concentration of the second valley portion.

16. The SiC semiconductor device of claim 1, wherein a vertical profile of the doping concentration of the first valley portion, the first plateau portion and the first transition portion is an in-situ doping concentration profile.

17. A method of manufacturing a silicon carbide (SiC) semiconductor device, the method comprising:
forming a buffer layer of a first conductivity type; and
forming a drift layer of the first conductivity type arranged, along a vertical direction, on the buffer layer,
wherein a vertical profile of a doping concentration of the buffer layer includes at least a first valley portion, a first plateau portion and a first transition portion extending from the first valley portion to the first plateau portion,
wherein a doping concentration of each of the first valley portion or the first plateau portion varies by less than 20 %, and
wherein a vertical extent of the first transition portion ranges from 1 % to 30 % of a vertical extent of the first valley portion.

18. The method of claim 17, wherein a vertical profile of the doping concentration of the first valley portion, the first plateau portion and the first transition portion is formed by in-situ doping.

19. The method of claim 17, wherein the buffer layer is formed on a SiC substrate by an epitaxial layer deposition process, and wherein the drift layer is formed on the buffer layer by an epitaxial layer deposition process.
